(19) United States
(12) Patent Application Publication
(10) Pub. No.: US 2020/0154594 A1
(43) Pub. Date: May 14, 2020

(54) MODULAR SYSTEM AND METHOD FOR MONITORING AND DISTRIBUTING POWER

(71) Applicant: Uncharted Power, Inc., New York, NY (US)

(72) Inventors: Jessica O. Matthews, New York, NY (US); Norma Sosa, New York, NY (US); Fabian Bruegger, New York, NY (US); Parth Singh, New York, NY (US); Benjamin Samuels, Newnan, GA (US); Liam Nethercott, New York, NY (US); Khoa Lam, New York, NY (US); Nicholas John Navarro, New York, NY (US)

(21) Appl. No.: 16/596,625

(22) Filed: Oct. 8, 2019

Related U.S. Application Data
(60) Provisional application No. 62/743,455, filed on Oct. 9, 2018.

(51) Int. Cl. H05K 7/14; H05K 5/02; H04Q 1/02

(52) U.S. Cl. CPC H05K 7/1492; H04Q 1/03; H04Q 1/025; H05K 5/0217

(57) ABSTRACT

The present invention discloses a plurality of modular containers. The modular containers can comprise a first container that includes a first top surface, a first bottom surface and at least one first side surface oriented between the first top and the first bottom surface. The first container can define a first internal cavity. The modular containers can also include a container system that is located in the first internal cavity. The modular containers can include a power distribution system and a data distribution system. In addition, the modular containers can include a second container. The second container can comprise a second top surface, a second bottom surface and at least one second side surface oriented between the second top and the second bottom surface. The second container can also define second internal cavity. Further, the modular containers can include a container subsystem located in the second internal cavity. The container system can also be in communication with the container subsystem.

### TECHNICAL FIELD

The embodiments of this disclosure relate generally to a container subsystem and more specifically a container subsystem in communication with a container system to distribute data and power throughout the network.

### BACKGROUND

With centralized processing, a centrally located computer system process data. Disadvantages of centralized processing include high costs in transmitting transactions, slow response time and large data storage. A decentralized data center leverages a distributed system, characterized as a system whose components are located at different physical locations which communicate and coordinate their actions by exchanging data. Decentralized data centers are not dependent on procuring one large plot of land to house all of the computation and storage components, as is required by a centralized data center. By distributing the system architecture, many benefits are added, such as decreasing the need for cooling, which accounts for approximately 20% of the operational expense for data centers. Within distributed data centers, however, there still exist many areas of improvement. The containers of the present invention aim to address those areas of improvement such as, but not limited to, physical space, aesthetic factors, installation convenience, upfront capital, energy requirements, pre-project planning, and convenience, along with energy transmission and monitoring.

### SUMMARY

An aspect of an embodiment of the present invention improves systems for power or energy, data, and fluid transmission and storage between modular systems of containers. The containers described herein can function as a replacement for standard flooring, sidewalks, and roads, or can seamlessly blend into the pre-existing environment. Wherever there is or can be ground, the containers can be installed. The containers create a piece of infrastructure, particularly a paver platform for embedding technology or hardware in, partially above, or completely above the ground.

In an aspect of an embodiment of the present invention, the system may also include a series of proprietary protocols so that users of the network (or the network itself) can distribute power or data automatically. The modular design with embedded functionality can reduce the cost of installing underground transmission lines, storage and management apparatus for power and/or data. Embedded sensors allow for precise monitoring and issue identification, so repairs can be addressed in hours instead of days, further lowering the cost of maintenance. Power generating devices and data center can also be incorporated into each container, enabling the containers to function autonomously, and as such do not necessarily require linkage to a larger system to provide value to users.

In an aspect of an embodiment of the present invention, when connected to other containers, the system creates a decentralized network for power access and/or data computing and storage that can adapt to the changing needs of the world around it. Features of the containers can include easy installation and repair, ease of repair location identification through smart monitoring, low cost, weather resistance, theft and tamper-resistance, aesthetic appeal, modularity and scalability, and durability, among others. The containers create a system that can also be leveraged for future technological advances, including embedded power generation, scalable power amalgamation, smart power mesh networking, and/or dynamic power or data distribution and storage, enabling distributed or parallel computing, among others. Embedded power generation would allow power harnessing devices to be directly integrated into the containers, housing the power source directly in the conduit itself.

The present invention discloses a plurality of modular containers. The modular containers can comprise a first container that includes a first top surface, a first bottom surface and at least one first side surface oriented between the first top and the first bottom surface. The first container can define a first internal cavity. The modular containers can also include a container system that is located in the first internal cavity. The modular containers can include a power distribution system and a data distribution system. In addition, the modular containers can include a second container. The second container can comprise a second top surface, a second bottom surface and at least one second side surface oriented between the second top and the second bottom surface. The second container can also define second internal cavity. Further, the modular containers can include a container subsystem located in the second internal cavity. The container system can also be in communication with the container subsystem.

The present invention also include another embodiment for the plurality of modular containers. The modular containers can comprise a first container that includes a first top surface, a first bottom surface and at least one first side surface oriented between the first top and the first bottom surface. The first container can define a first internal cavity. The modular containers can also include a container system that is located in the first internal cavity. The container system can include transmitting system data. The second container can comprise a second top surface, a second bottom surface and at least one second side surface oriented between the second top and the second bottom surface. The second container can also define second internal cavity. Further, the modular containers can include a container subsystem located in the second internal cavity. The container system can also be in communication with the container subsystem.

The present invention can include an additional embodiment comprising a modular container. The modular container can include a first top surface, a first bottom surface and at least one first side surface oriented between the first top and the first bottom surface. The first container can define a first internal cavity. The modular containers can also include a container system that is located in the first internal cavity. The container can also include a conduit through the modular container. The conduit can transmit at least one of: electricity, light, data, solid, liquid, or gas. The modular container can also include a container subsystem in the first internal cavity, wherein the container subsystem stores, monitors, and communicates the modular container data. Other embodiments, features, and aspects of the disclosure are described in detail herein and are considered a part of the claimed disclosure. Other embodiments, features, and aspects can be understood with reference to the following detailed description, accompanying drawings and claims.

### BRIEF DESCRIPTION OF THE DRAWINGS

The accompanying drawings, which are included to provide a further understanding of the invention and are incorporated in and constitute a part of this specification, illustrate preferred embodiments of the invention and together with the detail description serve to explain the principles of the invention.

FIG. 1 is an isometric exposed view of a container subsystem oriented within the internal cavity of a container.

FIG. 2 is an exploded isometric view of a container subsystem.

FIG. 3 is an isometric exposed view of a container system in a first container and container subsystem within a second container.

FIG. 4 is a partial top exposed view of a container system in a first container and container subsystem within a second container, where the container system is in communication with the container subsystem.

FIG. 5 is an electrical schematic of the container system or the container subsystem.

FIG. 6 is a schematic of the software and hardware for the dual network with cloud storage, and a dashboard shown as the graphical user interface.

FIG. 7 is a display of the graphical user interface display of the distributed data system health.

FIG. 8 is an electrical schematic of a smart monitoring system that integrates multiple containers.

FIG. 9 is an electrical schematic of a container system and container subsystem in a container.

FIG. 10 is an electrical schematic of a container system and container subsystem in FIG. 3

FIG. 11 is an electrical schematic of a sensor network

FIG. 12 is a layout of a plurality of container systems and container subsystems in an edge colocation arrangement

### DETAILED DESCRIPTION

Whenever appropriate, terms used in the singular also will include the plural and vice versa. The use of “a” herein means “one or more” unless stated otherwise or where the use of “one or more” is clearly inappropriate. The use of “or” means “and/or” unless stated otherwise. The use of “comprise,” “comprises,” “comprising,” “include,” “includes,” and “including” are interchangeable and not intended to be limiting. The term “such as” also is not intended to be limiting. For example, the term “including” shall mean “including, but not limited to.”

The following description is provided as an enabling teaching of the disclosed articles, systems, and methods in their best, currently known embodiments. To this end, those skilled in the relevant art will recognize and appreciate that many changes can be made to the various aspects of the articles, systems, and methods described herein, while still obtaining the beneficial results of the disclosure. It will also be apparent that some of the desired benefits of the present disclosure can be obtained by selecting some of the features of the present disclosure without utilizing other features. Accordingly, those who work in the art will recognize that many modifications and adaptations to the present disclosure are possible and can even be desirable in certain circumstances and are a part of the present disclosure. Thus, the following description is provided as illustrative of the principles of the present disclosure and not in limitation thereof.

As used throughout, the singular forms “a,” “an” and “the” include plural referents unless the context clearly dictates otherwise. Thus, for example, reference to “a gasket” can include two or more such gaskets unless the context indicates otherwise.

As used throughout, “substantially” with respect to a measure can refer to a range of values comprising +/−10% or +/−10 degrees. For example, substantially orthogonal, normal, or parallel can include embodiments, where the referenced components are oriented +/−10 degrees of being classified as orthogonal, normal, or parallel respectively.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

The word “or” as used herein means any one member of a particular list and also includes any combination of members of that list.

The containers described herein can function as a replacement for standard flooring, sidewalks, and roads, or can seamlessly blend into the pre-existing environment. The containers can create infrastructure, particularly a conduit for embedding technology or hardware in the ground. The containers, however, can be partially above, or completely above the ground. The containers can be leveraged by a myriad of applications, including power transmission, smart monitoring, and decentralized data centers. Once the system containers are installed, they can serve as containers for a ubiquitous and on-demand source of power and/or data that is accessible wherever and whenever power and/or data are needed. The modular design and embedded functionality can reduce the cost of installing underground transmission lines for power and/or data. Further, embedded sensors in the container can facilitate precise monitoring and issue identification, so repairs can be addressed in hours instead of days, further lowering the cost of maintenance.

Further, the container subsystem serves as a colocation space for internet of things (IoT), edge computing devices, and other equipment or tools. For example, the container subsystem can serve as a colocation space for battery packs for back-up power, sensors, radios, wireless antennas, communication electronics, distributed data center components, servers, cables (e.g., power, fiber optic, Ethernet, audio), electronics, mobile devices, digital storage, power generation devices, emergency equipment (e.g., medical, power), and tools. The internal cavity in the container can be rented out to customers.

To allow for changing, upgrading, and addition of systems inside the colocation space, the container subsystem can be opened after installation by qualified personnel. Customers will be trained on safe use of the system and only qualified personnel will be able to work inside it. A photodiode sensor can also be provided to detect opening of a cover.

Further, power generating devices and data center components can also be incorporated into each container. In such a configuration, the containers can function autonomously, and may not necessarily require linkage to a larger system to provide value to users. Similarly the container subsystems and container systems can act with autonomy independent from the external components they are oriented in. However, when connected to other containers, the system can create a decentralized network for power access and/or data computing and storage that can adapt to the changing needs of the world around it.

Features of the containers can include easy installation and repair, repair location identification through smart monitoring, low cost, weather resistance, theft and tamper-resistance, aesthetic appeal, modularity and scalability, and durability, among others. The containers create a system that can also be leveraged for future technological advances, including embedded power generation, scalable power amalgamation, smart power mesh networking, and/or dynamic power distribution, among others. Embedded power generation would allow power harnessing devices to be directly integrated into the containers, housing the power source directly in the conduit itself. Scalable power amalgamation allows for the efficient collection and storage of smaller packets of power, often generated by multiple different sources. This allows for a larger, more consistent stream of power to become available for use from one output. With both embedded power generation and scalable amalgamation housed within the containers, a complete solution for power generation, storage, and transmission is provided. Smart power mesh networking can utilize the network architecture that the containers are able to create, paired with intelligent communication and power prioritization protocols to efficiently and intelligently transmit power. Short and long-range electricity, the Internet of Things, decentralized cloud computing, edge computing, and data utilization for block chain and autonomous vehicles are a few industry examples that directly benefit from the container described herein and the systems built with them.

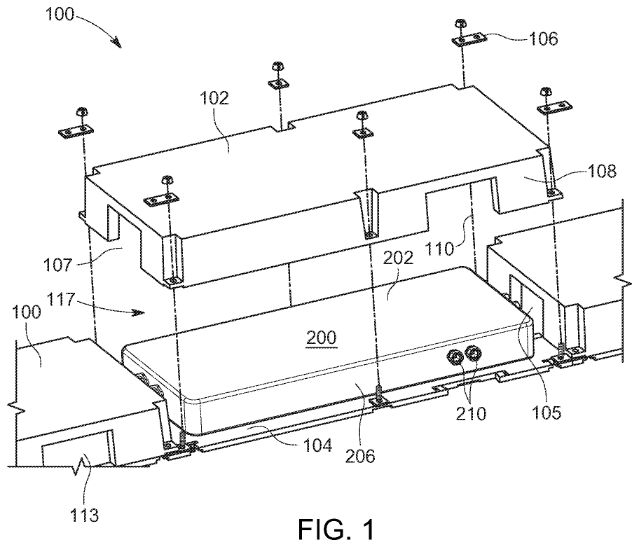

As shown in FIG. 1, the exploded view illustrates the layout of the container 100 comprises a bottom surface 104; a top surface 102; external side surfaces 108; and fasteners 106 to provide support for the container and increase its stability and robustness. As will be appreciated, any combination of the components mentioned above may be used to construct the containers described herein. In some instances, the container may have additional components (e.g., additional fasteners, supports, or a variety of other options). In some cases, the side surface(s) 108 can permanently connect to the bottom surface 104 and/or the top surface 102 to create one complete piece.

In some instances, the container 100 can comprise fiber reinforced polymer (FRP), one or more plastics, one or metals, a combination thereof, or any other material. Fiber reinforced polymer (FRP) can be used to create an extremely durable container, as well as customizable aesthetics. For example, the top surface 102 can be structured to resemble pavement. While resembling pavement, the top surface 102 can be configured with texturing to ensure that it is a non-slip surface. In some aspects of the container, the top surface 102 can comprise fiber reinforced polymer for durability and structural stability. In a further aspect, the top surface 102 can be customized to blend into an existing environment or create a new appearance or environment within an existing environment. The top surface 102 may also comprise a protective transparent surface exposing underlying lighting devices (such as LEDs), in order to provide an interactive experience or navigation assistance. The top surface 102 is a load-bearing member can bear the weight of large objects and structures ranging from pedestrians to vehicles, for example.

The one or more side surfaces 108 can have one or more ports 110 that parallel one or more ports in the side surfaces. The number of ports 110 can easily be adjusted depending on the pattern and/or layout that the containers intended for the installation. These ports 110 can be used for the passage of various conduits through the container 100. The ports are cutout or openings sized to receive the conduits. If the ports 110 are not being used they can be filled using the port plugs 113. Ports 110 can be oriented between the top and the bottom surface. In a further aspect, the ports 110 can be identified as an entrance port 105 from the container 100 or an exit port 107. In addition, the inside of the container defines an internal cavity 117, which is between the top surface and bottom surface. FIG. 1 also includes the container subsystem 200. The contain subsystem comprises a lid 202 depicted in a closed configuration. In addition the container subsystem can have ports 210 and sides 206.

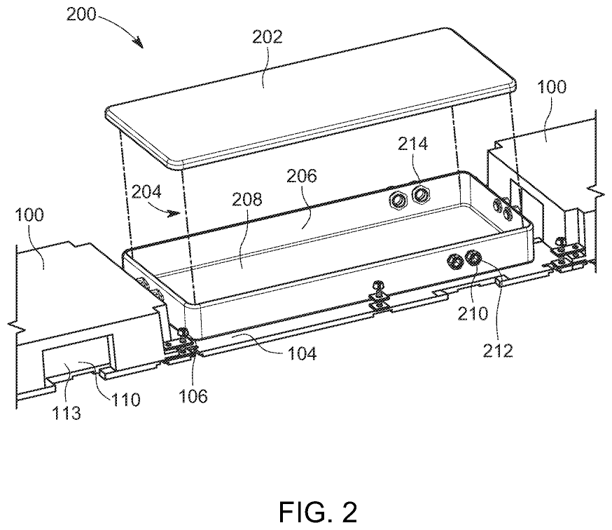

FIG. 2 is an isometric exposed view of a container subsystem 200 situated in the internal cavity 117 of the container 100. The container subsystem can comprise a lid 202. In one aspect the lid 202 can be separated from the container subsystem 200 to provide access to the interior 204 of the container subsystem 200. The interior 204 of the container subsystem 200 is the internal surface between the base 208 and lid 202. In a further aspect, the container subsystem can comprise a sides 206 that are positioned between the lid 202 and base 208. In yet a further aspect, the container subsystem sides 206 can define container subsystem ports 210. The container subsystem ports can provide an access to the interior 204. In a further aspect, the container subsystem ports 210 can be further classified to be a container subsystem entrance port 212 or a container subsystem exit port 214. In addition, the direction of flow through the port can be altered either physically be a user or connected to regulating device such as a processor 148 (not shown).

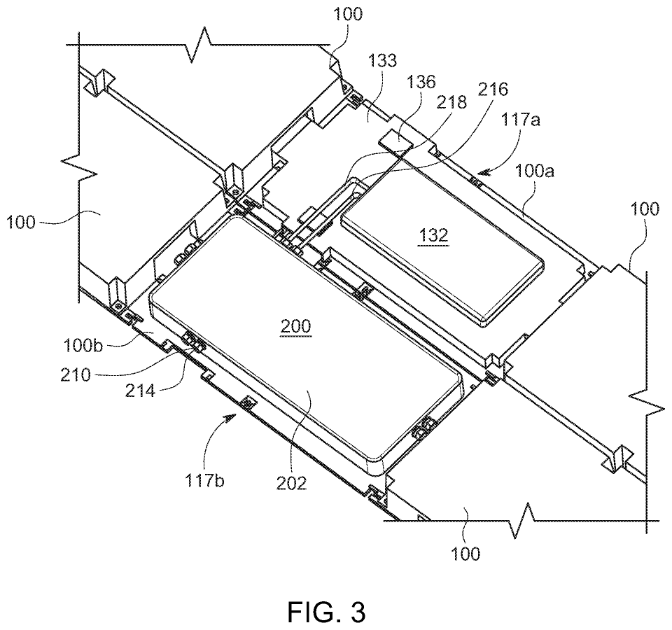

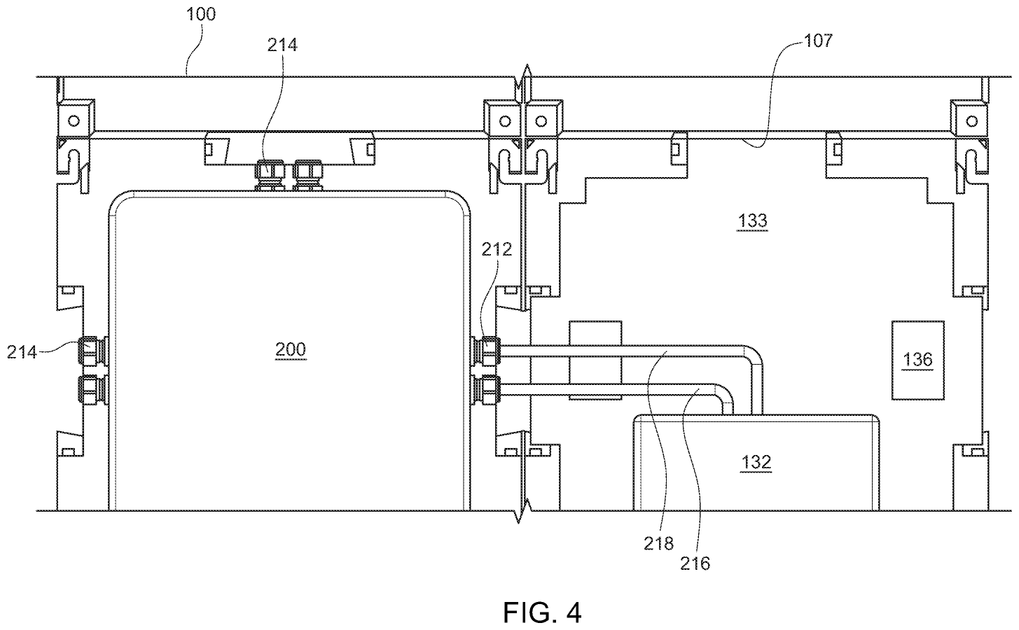

As shown in FIG. 3, the containers can be expanded to increase functionality. As shown in FIG. 3, there are two containers 100A and 100B with their respective interiors 117A, 117B exposed by removing the top surface 102. Exposing the respective top surfaces 102, shows that a first container 100A can have a container system 132 in its interior 117A. Similarly, a second container 100B can have a container subsystem 200 in its interior cavity 117B. In an alternate view, as shown in FIG. 4, the container subsystem 200 and the container system 132 can be placed in communication with each other. For example, a power cable 216 can transfer power from the container system 132 to the container subsystem 200. In a further aspect, a communication line 218 can transfer data between container system 132 and the container subsystem 200. In addition, the ports 210 of the container subsystem can be aligned with the ports 110 of the container 100. Similarly, ports defined by the container subsystem 132 can be aligned with the ports 110 of the container 100. In yet a further aspect, the relative ports of the containers 100, container system 132 or container subsystem 200 can be configured to be bi-directional. In yet a further aspect, an alternate embodiment can comprise a single container 100, wherein both the container subsystem 200 and the container system 132 are both housed in the same container. This configuration can allow for an economy of space and resources.

The container system can provide a cover 133. The cover 133 can be used to provide security protection to the conduit in the event that the internal cavity 117 of the container 200 is accessed. In a further aspect, the cover 133 can be configured to provide environmental protection to the conduit (not shown). The cover 133 can provide protection from environmental factors. For example, the cover 133 can be based on being made of a waterproof and/or ultraviolet resistant material. In other aspects, the cover 133 can provide protection from wind and in yet another aspect the cover can constructed with increased durability to protect the container system 132 in the event of an earthquake or event that affects the load bearing capabilities of the container system 132. The cover 133 can also be constructed to provide a hermetic seal to prevent air, water, or persons from accessing the conduit. In an embodiment, the container cover 133 can provide insulation from the high-potential conduits and create additional space between the cover 133 and the top surface 102 of the container for other devices, sensors, conduits, among others. Similar to the cover 133, the container subsystem 200 be configured to provide environmental protection to the container subsystems interior components. For example, the lid 202 can be hermetically sealed to prevent air or moisture from entering. In another aspect, the container system ports 210 can be sealed. As discussed earlier, the cover 133 can be a component of both the container system 132 and the container subsystem 200. In a further aspect, the cover 133 can have dimensions and structure similar to a NEMA (National Electrical Manufacturer Association) box.

The container system can also comprise a second type of monitoring sensor 135 to monitor conduit properties. In a further aspect, when the conduit is an electrical passage the conduit properties can be used to measure voltage, current, ground fault. When the second type of monitoring sensor monitors a chemical or fluid, conduit properties can include but not be limited to fluid flow, pressure, pH, temperature, or viscosity. When the conduit 111 is a fiber optic cable, the second type of monitoring sensor 135 can monitor conduit properties such as optical time delays, luminosity of the light signal, scattering, light or dark monitoring, or reflectivity of the conduit tubing.

In yet another aspect, the container system 132 can be configured for installation of subsequent conduit components. For example, if additional lines of transmission are added to the conduit (not shown), the potted nodes 136, in FIG. 3, can be integrated to provide access to the conduit. The potted nodes 136 can comprise access to the conduit that are inert because they may have been sealed off. For example, a potted node 136 can be capped off with an epoxy or resin to prevent access to any components of the conduit. When a user seeks to provide an access to the conduit, the potting substance such as but not limited to plastic, resin, silicone or rubber may be used. In a further aspect, the potted nodes can be oriented to align with a port 110 to allow a user to more efficiently be in proximity to an access point of the conduit from the power transmission line 141.

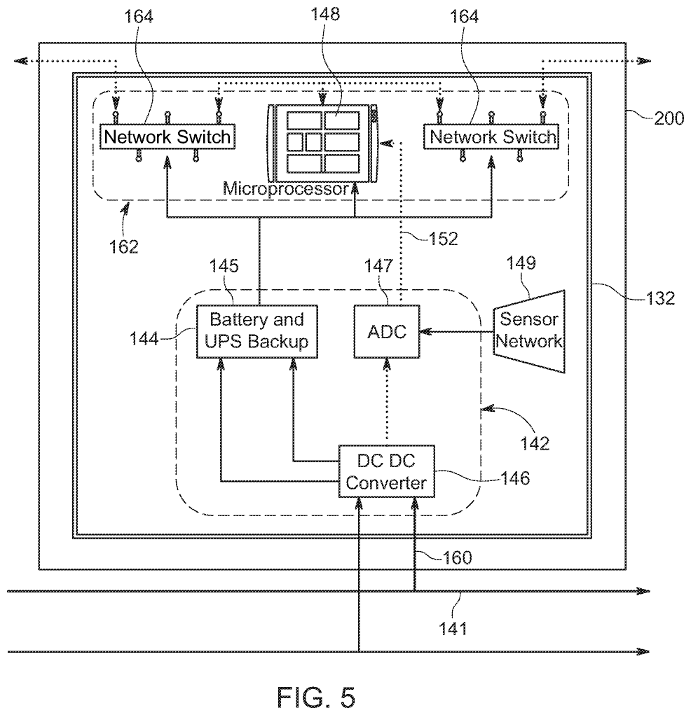

In yet another aspect, as shown in FIG. 5, the container system 132 or container subsystem 200 can also include a power distribution device 142. FIG. 5 is a schematic depicting subcomponents of the container system 132 or of the container subsystem 200. In an alternate embodiment of the plurality of containers, in one aspect, the power distribution device 142 can comprise power received from a power conduit 160. In another aspect the power distribution device 142 can be a localized power source such as a battery 144. In a further aspect, power to power conduit 160 can be received into the container from a power transmission line 141.

Referring back to FIG. 5, the power distribution device 142 of the container system 132 can provide power to the container subsystem 200. In a further aspect, the container subsystem 200 can be configured similar to the container system wherein the container subsystem can comprise its own power distribution device. In an alternate embodiment, the container subsystem 200 can be configured to receive or generate power independently from the container system 132. For example, the container subsystem 200 can include its own battery or power generation medium such as solar panels. In a further aspect, the container subsystem 200 can receive its own power supply through an alternate set of power transmission lines 141. The power to the container subsystem 200 can be supplied by the container system 132. In another embodiment, the container subsystem 200 can supply power to the container system 132.

In a further aspect, the voltage or current supplied by the power transmission line 141 may not always be properly suited to power the container 100 or the container system 132. In a further aspect, the power distribution device 142 can comprise multiple components with the purpose of altering power to the container system 132. As shown in FIG. 5, the power distribution device 142 can include a power supply 144, wherein the power supply can be a battery. In a further aspect, when the main source of power to the container system 132 is supplied by the power transmission lines 141, the battery 144 can serve as an auxiliary power supply for the uninterrupted power supply UPS 145, which powers the processor 148, in the event that power from the power transmission lines 141 fail.

Further, when the power is supplied by the power transmission lines 141, the power distribution device can also include a converter 146. The voltage converter 146 can be used to step up or step down the voltage as needed, as one of various forms of power conditioning. For example, a 110/220 voltage may be converted to a 220/240 and vice versa using a DC-DC converter 146. In another aspect, the power distribution device 142 can include an AC to DC rectifier which converts direct current to alternating current and vice versa. Converting input power may be necessary because the sensor network 149 can function under alternating current AC but the power may be supplied with direct current (DC). The sensor network can include a first type of monitoring sensors, the second type of monitoring sensors and collecting sensors can function under alternating current. In some embodiments, an analog to digital converter (ADC) 147 can be used to convert signals from the sensor network 149 from analog voltage or analog current form to digital format to be used by the processor(s) 148.

Referring back to FIG. 5, the container system 132 or the container subsystem 200 can comprise a sensor network 149. The sensor network 149 can comprise a plurality of sensors. Further the sensors can be categorized into multiple categories. The first category of sensors can be monitoring sensors. The monitoring sensors can be attached to internal components of the container system 132 or the container subsystem 200. For example, these sensors can be attached to the network switches 164, the processor 148, and/or to the top surface 102 of the container. The monitoring sensor can be configured to measure and monitor multiple types of container system data and/or to monitor conduit properties. In one aspect, the system data can comprise a status of container system or container subsystem such as the container system being active versus container system being inactive or a container being connected system versus container system being unconnected. Similarly, the system data can comprise a status of container system or container subsystem such as the container system being active versus container system being inactive or a container subsystem being connected versus the container subsystem being unconnected.

A second type of sensor can be used to measure voltage, current, ground fault, and the like. The measured data can be analyzed and processed by one or more processors 148, electrically coupled to the plurality of sensors in the sensor network 149, to obtain a variety of derived information. The derived information can provide further insight into the performance of the electrical transmission lines. The plurality of sensors may quantify other variables such as power quality, phase, reactive power, and power factor.

The container system 132 and container subsystem 200 can comprise a plurality of second type sensors to monitor one or more performance metrics for the conduit. In some instances, the plurality of sensors may comprise one or more voltage sensors. The voltage sensors may be used to determine the presence, absence, and/or amount of voltage in one or more sections along an electrical transmission line 141. The voltage sensor may be customized to include a printed circuit board (PCB). Customized voltage sensors may be integrated into one or more processors.

Further, a collecting sensor can be used to capture environmental information or environmental conditions external to the container system 132 or container subsystem 200. The environmental conditions such as temperature, humidity, light a motion can be captured by this type of sensor. For example, external conditions can be captured by vibration sensor or microphone. The microphone can be used to listen to capture audio signal or take a decibel reading in proximity to the container subsystem 200 or container system 132. In another aspect, the collecting sensor can include a photodiode. In a further aspect, the container subsystem 200 or container system 132 can have a plurality of photodiode sensors such that if various locations of the container are accessed, then a signal would be provided. For example, if the embodiment of the container includes the container system cover 133, then one photodiode sensor can be placed under the cover 133 and a second photo diode sensor can be placed in proximity to the top surface 102. Accordingly, the processor 148 can receive signals that indicate when light has reached those regions of the container 100.

In a further aspect, the container system 132 can comprise a data distribution system 162. In a further aspect, the data distribution system 162 can comprise network switches 164 and a processor 148. The processor 148 can be tasked with processing the container system data. The container system data can comprise the data generated internally by the container system 132 and data received into the container system. For example, when a collecting sensor and the first or second type of monitoring sensors receive input from a stimuli, a signal can be generated. The processor 148 can process the received container system. Processing the container system data can include distributing the data to other components of the container system or container 200; outputting the data for display to an auxiliary system such as the graphical user interface; or generating a feedback response based on pre-programmed instructions stored by the processor 148. In a further aspect, the processor 148 can communicate with other components of the container system 132 or container subsystem 200 through the network switches 164. In yet a further aspect, the data distribution system 162 comprising the processor 148 and network switches 164 can communicate with the other components of the container system 132 via a data conduit 152. The data conduit 152 can be an internal communication conduit to send and receive signals between the components of the container system 132 and the container subsystem 200. In this embodiment, the network switches 164 may be used to determine which path of the data conduit 152 to take. Similar to the discussion of power supply, there can be an embodiment wherein the container subsystem 200 communicates independently from a communication path or a larger network in communication with the container system 132. In this embodiment, the container subsystem 200 are only in communication to each other. In addition, the container subsystem can comprise a data distribution device 162 similar to the container system 132, wherein the container subsystem 200 switch between the same data distribution network of the container system 132 or communicate on an independent network. In a further aspect, switching between the data distribution networks can be based on a manual switching or instructions received from a processor 148.

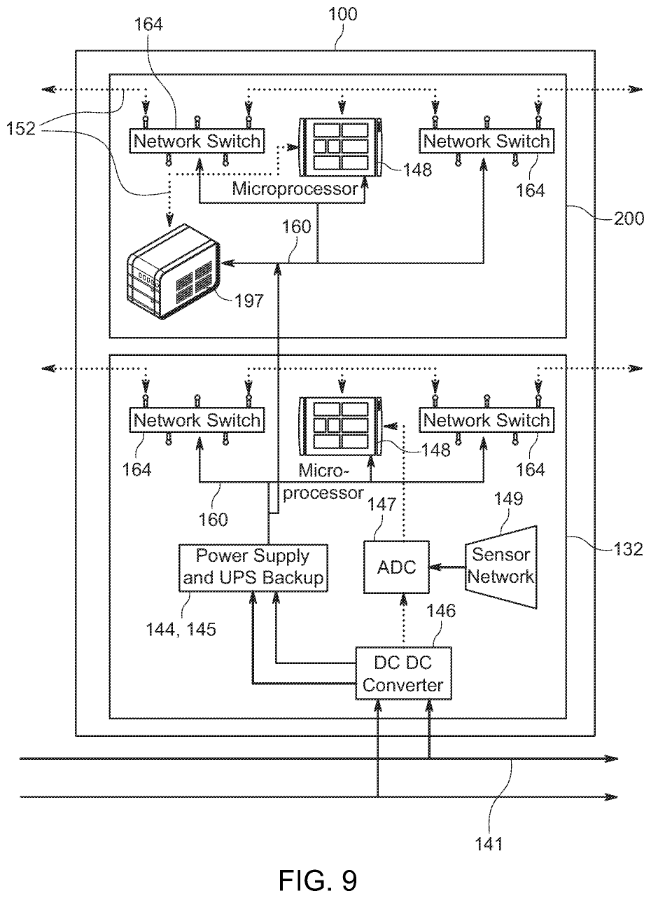

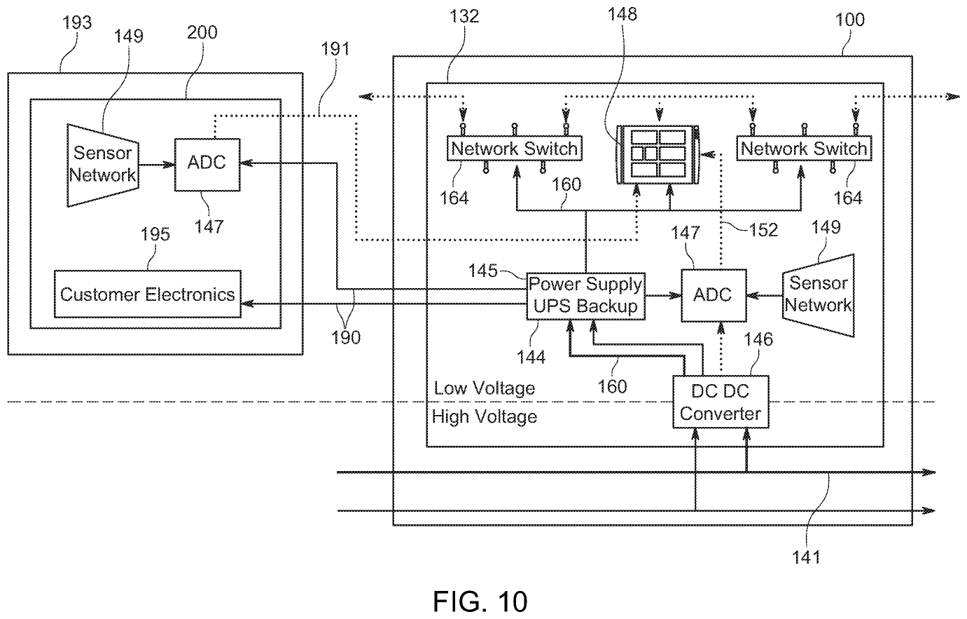

FIG. 9, is an alternate embodiment of FIG. 3 and FIG. 4 because, the container system 132 and the container subsystem 200 are oriented in the same container 100. The physical components depicted in FIG. 5 are similarly included in the embodiments of FIG. 9 and FIG. 10. Further, the container subsystem 200 or container system 132 may contain one or more RAID (redundant array of independent disks)-based data storage. The data can be stored on the RAID storage 197 before and/or after the data has been processed by the one or more processors. In some cases, data may also be stored, processed, and then uploaded to a cloud-based system. The RAID storage 197 may include one or more physical hardware, such as a Solid State Drive (SSD), a Hard Disk Drive (HDD), M2, to name a few. In addition to the RAID data storage system, there can be multiple levels of redundancy. The level of redundancy level can be increased based on a number of factors, including the amount of data processed by the processors.

FIG. 10 is an alternate embodiment of FIG. 9 depicting the communication and power distribution paths between the container subsystem 200 and container system 132, as shown in FIG. 3. Low voltage power 190 and communication cables 191 are extended from the container system 132 to provide power and communication to the edge system 193 of the container subsystem 200. A sensor network 149 in the container subsystem 200 may provide data to the container system 132. Data flows between the container subsystem sensor network 149 and any edge colocation electronics 195 in the container subsystem 200 to the container system 132 via a data connection. The colocation electronics can be third-party customer electronics from the company renting or using the container subsystem 200

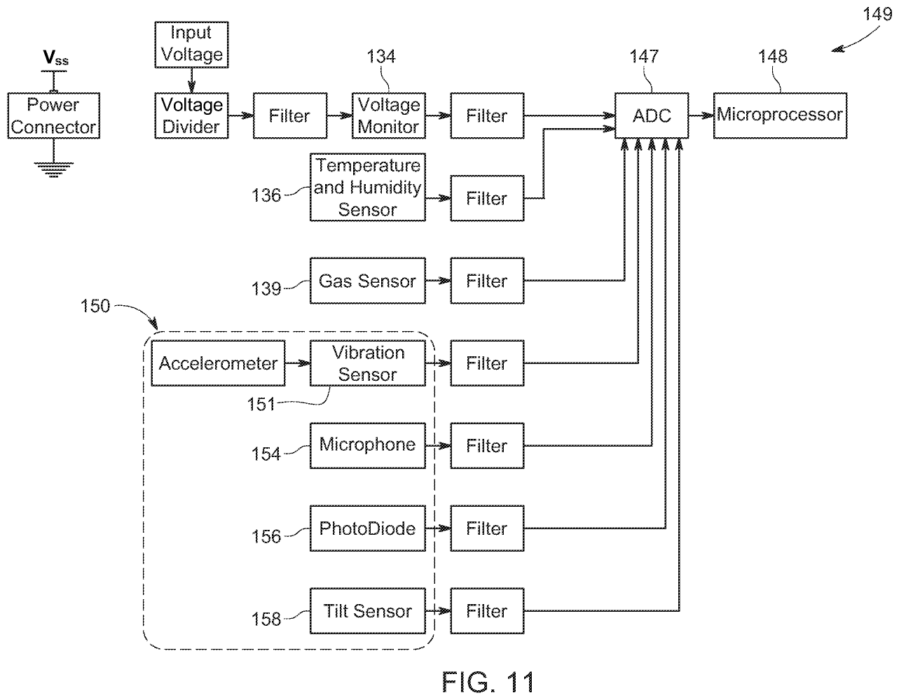

FIG. 11 shows an electrical schematic of the sensor network 149 depicted in FIGS. 5, and 9-10. The sensor network can comprise the first type of monitoring sensor, the second type of monitoring sensor and the collecting sensors 150. Here, the collecting sensor 150 can include hardware such as accelerometers to be a vibration sensor 151. The collecting sensors 150 can also comprise a microphone 154. The microphone 154 can be used to listen, to capture audio signal or take a simple decibel reading in proximity to the container system 132 or the container subsystem 200. In another aspect, the collecting sensor 150 can include a photodiode 156. The photodiode 156 can be used to receive any light signals from outside the container. In a further aspect, the sensor network 149 can include a tilt sensor 158 or a vibration sensor 151. The external data captured by these sensors is inputted from vehicles, pedestrians, air quality, or sound quality monitored in relation to the container. The humidity sensor 136 would provide information about the moisture level inside the container and/or the container system as a function of environmental conditions, providing an early detection system to avoid electronic shorting, damage, or general faults.

Gas sensors 139 can be utilized to detect a variety of exhaust fumes from system, entering the system, and to monitor the microclimate surrounding the system. If the conduit carries gas mediums, the gas sensors can provide protection and data for an early warning system for leak detection and help avoid explosions or other chemical hazards. Humidity and gas sensors typically operate by detecting electrical charges, electrical resistance, or electrical current changes or across or on a material set.

In addition, the processor 148 can communicate with the container system 132 and interprets the outputs from the container system data. The output from different sensors are affected by noise or bias in a variety of ways. For example, an accelerometer data may drift away from baseline and may require routine calibration, whereas a microphone sensor can easily be affected by electromagnetic fields near the sensor, and a voltage sensor may be sensitive to harmonics or noise in the system. Different filters, either hardware and software based, are designed to filter out the noise and bias in the data to report accurate data from the sensors. Examples of these filters include but are not limited to software based re-calibration of accelerometer data and a hardware R-C circuit for a voltage sensor. These filters would provide improved quality of container subsystem data.

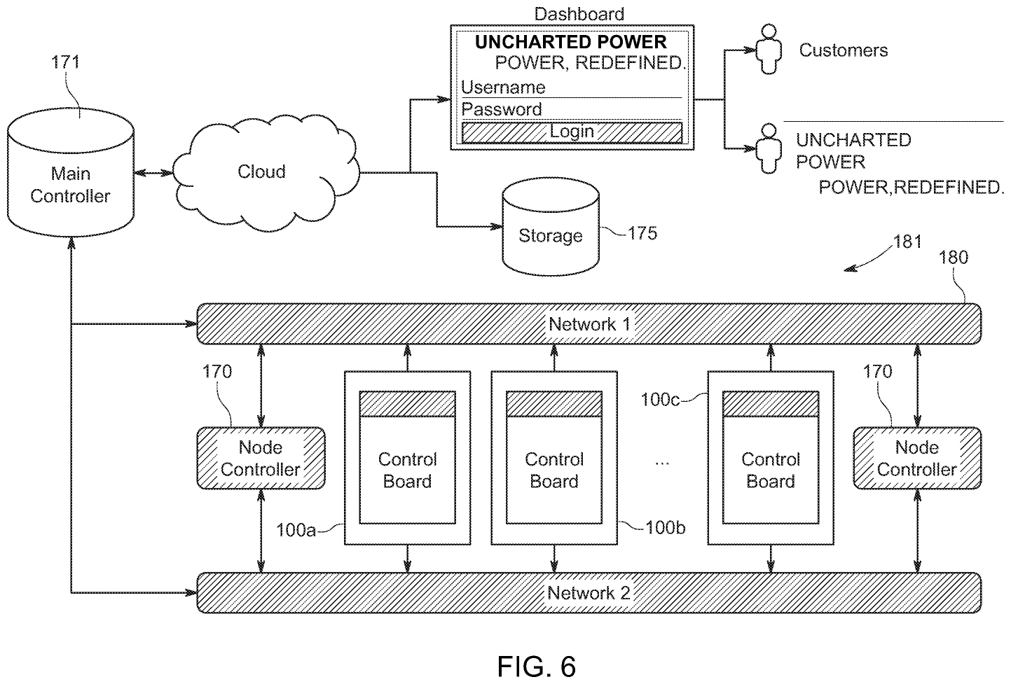

In a further aspect, the data distribution system 162 of one container can distribute data to a second container. As shown in FIG. 6, containers can communicate with each other. In a further aspect, the monitoring completed by a single container 100A can be extended to generate monitoring and data distribution between multiple containers 100B, 100C. The containers 100A-C can be connected to each other via Ethernet, Internet, or wireless communication such as Bluetooth or RF signal. In addition, the containers can be connected to a controller or node controller 170. The additional containers 100B and 100C can comprise another container system 132 or a container subsystem 200. In some cases, the controller 170 may be housed near a power destination. In this embodiment, the power distribution network and the data distribution network can work in concert with each other.

As shown in FIG. 6, network of data distribution devices 180 in each container system can form a distributed data center 180. In some embodiments, the one or more containers can use several electrical and/or mechanical components including power transmission lines, processors, switches, and Ethernet connections.

In addition to one or more containers, the distributed data center 180 can comprise one or more controllers 170. The one or more controllers may be housed outside of the container. In some cases, the one or more controllers 170 may be located within the power destination, or near the power destination. The one or more controllers can support a function of the other components of the distributed data center 180, power source, power destination, or a combination thereof. For example, the controller 170 can connect to a processor 148 or a system of processors 148 within one or more containers 100. Further, the data distribution center 180 may connect the one or more controllers 170 to processors 148 as a network. Accordingly, this network may allow the exchange of information. For example, data may be collected from one or more power meters (not shown). The data can then be transmitted to processors 148 through the network for further processing. In some cases, the respective container system data can be transmitted to a cloud-based system instead of the processors, especially if the data is for emergency purposes or is to be processed in another facility. The one or more controllers 170 can be responsible for determining where the data is to be transmitted.

The one or more controllers 170 can provide several functions to the system. In some cases, the one or more controllers are important for metering as the controller determines what type of data is to be collected. In some cases, the one or more controllers are important for networking; for example, the controller can utilize a dynamic host configuration protocol (DHCP) to inform the network of the different available network connections.

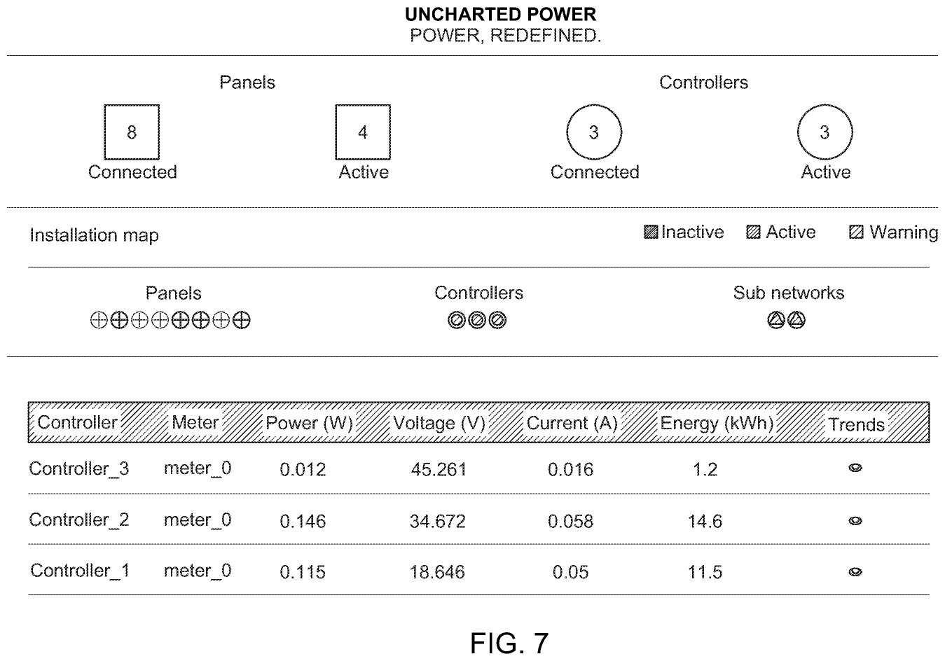

The activity exhibited by the network components in FIG. 6 can be summarized by the visual display in FIG. 7. The status of each of the components shown in the network of FIG. 6 can be summarized in the visual display. Accordingly, an administrator can monitor the summary in the visual display and make decisions. The status of the container system 200 or the container system 132 can be used by the system administrator to determine an overall health of the container system, container subsystem and/or the data network 180. In another aspect, monitoring the container system data can include identifying, switching, or regulating a network component associated with a container 100. For example, the display identifies the active and connected panels (containers). A similar set of data can be determined for the controllers. In addition, electronic measurements can be provided for each of the components in the network 180. In a further aspect, the information displayed for containers 100, can also be displayed for container systems or container subsystems. The display in FIG. 7 can also be formatted to shown the interaction between the container system 132 and container subsystem 200.

Referring back to FIG. 6, in some cases, the one or more controllers can collect data or otherwise facilitate data collection. For example, one or more processors 148 can collect the data via the first type of monitoring sensors 134. The collected data can be transmitted to the controller 170 for processing, local storage, or cloud storage at either the container system 132 or container subsystem 200. In some cases, the controller may determine if the unprocessed data should be transmitted to the processors to be computed. Additionally, the controller 170 may also determine if the data should be transmitted to the storage equipment to be stored.

In some cases, the one or more controllers monitor a number of variables related to safety such as the overvoltage relays, overcurrent relays, switches, to name a few, throughout the system. Additionally, the controller 170 can check the status of one or more system safety devices to confirm the system safety devices are operating at status quo. In yet a further aspect, the data processed by the controllers can be further processed by the main controller 171, as shown in FIG. 6. At the main controller 171, data can also be routed, calculated or processed for storage.

In addition to the functions described herein, the one or more controllers 170 may play additional roles. For example, smart monitoring may be integrated into the controllers 170. In another example, the one or more controllers may connect with each other to communicate over a direct line for the purpose of transmitting errors, alarms, and other important or non-essential data.

The one or more controllers can be scaled up to comprise as many controllers as is needed to meet demand requirements and/or to increase the functionality of the system. In some cases, the data may need to be uploaded to a cloud-based data storage system 175. In those cases, at least one controller 170 should be connected to the Internet. This cloud-connected main controller 171 is then able to communicate with the other connected controllers. However, if there is no need to store data on a cloud-based system, the controller does not need to be connected to the Internet.

In some embodiments, the container system 132 or the container subsystem 200 may contain one or more processors 148. The processors may be responsible for processing some or all the data collected. The data to be processed may not have to be collected on the same site. Data can be sent to the distributed data center to be processed. For example, a company may send pre-existing data packages (protocols) to the system to be processed and then returned back. The data can be collected on site and then sent to an alternate site to be processed. In a further aspect, data can be received by a first container system 132 and sent to a second container system. Again, the controller 170 or protocols may make a determination as to which container system 132 will process the data. The decision may be based on system utilization of processor and the capacity of the processor.

Each of the one or more processors 148 can comprise a single core, a dual core, or a multiple core. The number of cores can be as high as needed to support the requirements of the system. The more cores that are included, the more computer systems can be used at a single point.

The processors may be connected to the controllers, which determine how they operate through the network 180. In addition to connecting to the controller 170, the one or more processors 148 can be connected to other processors through the network 180. The processors can be connected to each other and to the controllers in any combination that is feasible. The container can comprise as many processors as needed by the system.

In some embodiments, one or more processors can have a higher computing power to facilitate computing and data distribution. As shown in FIG. 6, the system comprising the distributed data center 180 may comprise a network 181 for hardware, such as a physical connection between the one or more controllers and the one or more processors. The connection between the one or more controllers 170 and the one or more processors 148 can enable the exchange of data between a controller and a processor in the container system 132, and/or the container subsystem 200. In addition, the network 181 may contain additional components such as one or more switches or media converters; one or more Ethernet and/or fiber optic cables, or similar. In addition to wired cables, the network can also be supported through wireless connections such as Wi-Fi and sound waves.

As mentioned earlier, the controller 170 can utilize a dynamic host configuration protocol (DHCP) to inform the network 181 of the different available network connections. In some cases, the software allows for automatic naming of sub-systems such as the one or more processors. In some cases, the software can assign an IP address or Internet protocol to the system and/or parts of the system. In other cases, the software may resolve an IP conflict.

The container subsystem can also have a self-sustaining power source since the container subsystem can be connected to one or more power sources, including power-generating sources. Power from the one or more power sources can be utilized to power one or more of the components contained within the container. For example, power of the container subsystem 200 is not always dependent on the container system 132. For example, power may be supplied wirelessly. In some cases, the power source is an electrical grid.

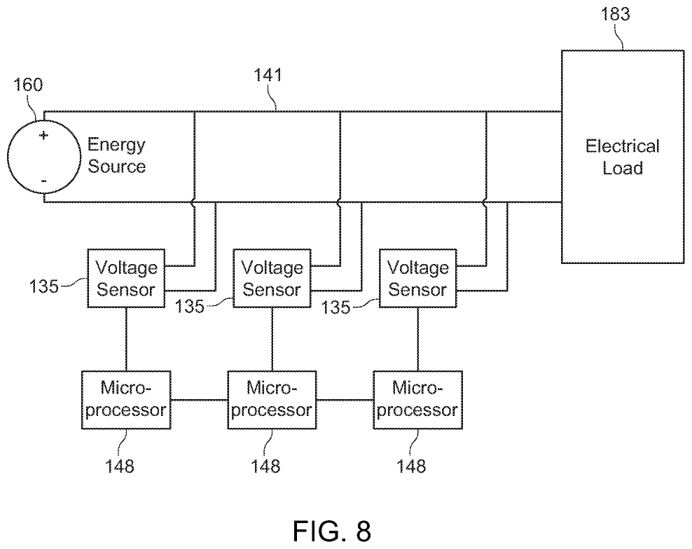

FIG. 8 provides an example layout of a smart monitoring system for electrical transmission lines (energy source) 141 either in the container system 132 and/or in the container subsystem 200. The smart monitoring system provided herein can be used in a number of applications. In one exemplary application, the plurality of sensors within the system comprises one or more voltage sensors. The one or more voltage sensors 135 check for the presence or absence of voltage in the transmission line being monitored, and communicate the results back to the plurality of processors 148. When there is a break or fault in a transmission line, the last sensor located before the break will read the open circuit voltage. The voltage differential determined using the last sensor can be used to locate the break or fault in the transmission line. In this exemplary embodiment, the plurality of processors can be powered by a battery or a power harvesting device. The power source may be located within the system or connected to the system via a power line.

The smart monitoring system can also be scaled to make additional analysis of a distributed data system 180 or power distribution system that spans multiple containers 100. The smart monitoring system comprises a power source 160. The power source 160 can comprise a power harvesting device, for example. Examples of power harvesting devices include devices for harnessing power from solar power or kinetic energy, triboelectric generators, piezoelectric generator, and the like. In some cases, the power source is an electrical grid, or a device connected to an electrical grid.

The power source 160 can be a direct current (DC) or alternating current (AC) generation source. In the case of an AC power line, a rectifier can be used to convert AC to DC. The converter 146 may be placed between a plurality of sensors and the transmission line(s) being monitored. If the power source is a DC input, a converter 146 may not be required. However, the DC input may be converted to higher or lower DC voltage using a DC-DC converter 146.

In scenarios wherein there is a fault or breakage in an electrical transmission line, the voltage sensor reading will either change drastically or read zero across adjacent sensors. The processor will receive this data and communicate this fault and its location to the controller.

The plurality of sensors can be located at any point between a power source 160 and power destination or electrical load 183. Barring any defects, external interruptions, additional devices, and/or other such interferences, the measured voltage will be the same throughout a transmission line 141.

The smaller the distance between each sensor, the more sensitive, effective, and efficient the sensor subsystem can be. For applications with long transmission lines, this can be achieved by adding multiple sensors. The number of sensors per distance can affect the detection and resolution of any faults. If the distance between any two sensors located along a transmission line 141 is short, any fault in the line can be detected with speed and precision as a short distance needs to be searched to locate the fault. In some cases, a DC-DC converter 146 can be used to step down the voltage before the voltage sensor takes a measurement. The use of a DC-DC converter can make it easier for the voltage to be read.

The smart monitoring system can also comprise a power destination such as an electrical load 183. An electrical load is an electrical component or portion of a circuit that consumes electric power. The electrical load can be any power drawing device. It can be an entire building, such as a residential home or school, or an individual device such as a street light, a Wi-Fi hotspot, or air conditioning unit, and the like.

The smart monitoring system can comprise a plurality of processors 148. The plurality of processors can be responsible for reading the sensor data collected by the plurality of sensors, processing the sensor data to detect any faults, and communicating the data and analyses. In some cases, some of the processors can be microcontrollers. Data lines can connect the plurality of sensors 135 to the plurality of processors 148 for communication.

In some embodiments, the plurality of processors 148 can communicate to a controller 170 through a network. The plurality of processors can be programmed based on what variable needs to be extracted. For example, real power can be calculated by extracting data regarding voltage and current of the lines through voltage sensors and current sensors.

Data integrity processes are used for protection or preservation of information reliability and continuity throughout its life cycle. Ensuring physical integrity requires measures including redundant components, a backup power supply, RAID arrays, utilizing file systems with block-level checksums such as ZFS, or using a cryptographic hash function and even a watchdog timer on sensitive subsystems. Common methods to maintain logical consistency include elements such as a check constraints, foreign key constraints, program assertions, and other run-time sanity checks. The system here utilizes several of these methodologies such as backup power supply, RAID storage, check sums, redundant components, check constraints, among others, to maintain data integrity.

The smart monitoring system can comprise a hardware-based network. The hardware-based network can be a physical connection between the one or more controllers and the plurality of processors 148. This connection enables the exchange of data between the controllers and the processors. The network may comprise two parts: (1) switches and/or media converters; and (2) Ethernet and/or fiber optic cables. In addition to wired cables, the network can also be supported through wireless connections such as Wi-Fi and sound waves. Alternatively, the network connects the one or more controllers to the plurality of processors and supports the exchange of information.

As shown in FIG. 7, the user interface can alert a user to the detection of one or more faults within the electrical transmission lines. FIG. 7 provides a graphical user interface for administrator to regulate and understand the flow of data and operations of the system as a whole. The smart monitoring system can further comprise a user interface. In some cases, the user interface is connected to the one or more controllers to obtain data. The data can be viewed by a user to learn about the status of the electrical transmission lines as determined by the sensors and the processors described herein. Once alerted, the user can then choose to deploy an appropriate maintenance protocol to correct or repair the fault. In some cases, the user interface is a digital surface or virtual surface. In some cases, the user interface is a website. In other cases, the user interface is an application that requires the user to log in. In some embodiments, the user interface can display or otherwise output (e.g., via sound) an automatic alert. The automatic alert may alternatively or additionally comprise an email or text message sent to a user's mobile device.

In another exemplary application, the plurality of the processors is equipped with power from a transmission line and an uninterruptible power supply (UPS). In some cases, a DC-DC converter may be used to step down the voltage. When there is a break or fault in the transmission line, the plurality of processors can switch over to the UPS system and will notify the one or more controllers of the change in power source. This change in power source can signal the development of a fault in the transmission line.

Beneficially, the smart monitoring system provided herein has the ability to pinpoint the location of a fault in an electrical transmission line with great speed and accuracy and provides advantages such as variable-resolution fault location identification, smart data acquisition, and proactive fault monitoring.

Variable-resolution fault location identification: the arrangement of container systems and container subsystems has the potential to detect a breakage or fault better than any other method currently available to the public. The resolution of fault detection can be increased to a very high degree by simply adding more sensors to the system. The distance between the sensors directly affects the resolution.

In a further aspect, the plurality of processors can be programmed to collect certain information automatically from a system. Valuable data can be collected while the system is operating normally. This data can be used in a variety of different situations and for a variety of purposes beyond just monitoring of the system, providing even more value. For example, container subsystem 200 can enable computing capability at the edge (i.e., underneath sidewalks or roads), some exemplary use cases include intersection/crosswalk traffic signals. When connected to the container subsystem, low latency can provide autonomous vehicles with complementary signals to coordinate agents on the roadway. Cars can react to traffic signals that are not necessarily physical, and these traffic signals may appear anywhere and react to stimuli from pedestrians, emergency vehicles, buildings, airborne vehicles.

Using traditional methods of detecting traffic at intersections, traffic light switching instructions may be stored in and actuated by the container subsystem. Additionally, machine learning algorithms may be implemented to efficiently automate traffic light switching. Furthermore, geo-temporal traffic data may be generated, stored, and acted upon within the container subsystem in order to provide digital signals, wirelessly, to autonomous vehicles. Alternatively, geo-temporal traffic data from a system of autonomous vehicles may provide a feedback system to coordinate traffic to maximum efficiency.

Other computing capability at the edge can be used for road toll collection in which a container subsystem could enable the subsystem to carry out the license plate recognition on a low-power single board computer close to the camera. The local compute power would carry out pattern recognition tasks to determine license plate numbers thus not requiring to transmit large image files to cloud or remote computing systems. A further field that may be enhanced by the innovation described herein is Augmented Reality and Virtual Reality world building. To construct these three dimensional interactive spaces, images can be both collected and processed/analyzed to recreate virtual experiences matching their physical likeness utilizing the local compute. Methods to achieve pattern recognition and AR/VR workloads typically lack enough powerful resources at the edge including compute, storage, and ultra-low latency network connection. Other examples of fields that will be enhanced by the computing capability at the edge described herein include but are not limited to: pushing advertisements at and for local points of interest, such as restaurants, to nearby devices; performing factory automation tasks; interaction with wearables; workplace safety and compliance; retail space and customer real-time analytics, aiding in dynamic inventory updates, shopping list support and targeted advertisement. Other general areas of use include multimedia streaming, uploading and downloading files for libraries and offline caches.

Edge computing can be used for on-site analytics for audience dynamics at stadiums, music venues, schools, hospitals, city and retail expansion planning and policy formation, among others. The local compute power can utilized in improvements for in-room conferencing technologies that circumvent cloud-based platforms and connectivity issues often experienced.

Proactive fault monitoring: with commonly-available underground electrical transmission systems, it is extremely difficult to locate faults. Visible detection requires a maintenance professional to descend below ground to investigate when a fault is identified. Often, fault identification only happens after a negatively-affected end user reports a lack of power. This is a reactive detection method as opposed to a proactive detection method. With the smart monitoring system described, proactive fault monitoring can be achieved. A fault and its location can be detected automatically and almost instantaneously. A quick and accurate identification of the fault can allow the fault to be fixed before it negatively impacts end users.

The application of the smart monitoring system is not only limited to electrical transmission lines. It can also be used to monitor data cables including but not limited to Ethernet, coaxial, fiber optic, serial cables, and token ring cables, among others.

Many power transmission systems are located above the ground and exposed to many elements that leave the system susceptible to damage and failure. In addition, the exposed power transmission system can be a safety hazard, endangering anything in its surroundings.

Provided herein is a power transmission system that can be embedded below ground level for a decentralized data center having data generation, collection, transmission, and storage capabilities. Locating the power transmission system below ground in this system provides several benefits including increased user safety, increased aesthetic appeal, increased speed of repairability, improved modularity and scalability, better financial feasibility, and easy installation.

The embedded power transmission system can comprise one or more containers in an arranged formation. For example, described herein, one or more power sources, and one or more power destinations. In some cases, the system of containers can be a power transmission system that transmits power from a power source (such as a power generating device) to a power destination (such as a power drawing device or a load). To perform its service, the container can be laid in any pattern to connect two or more points as needed. The two or more points can be any combination of power generating (or power harvesting) power supplies, power-neutral devices, and/or power drawing devices. In some cases, the containers can be leveraged to create infrastructure for full electrical micro-grids. The two or more points can be any infrastructure or device that is appropriate for the intended application.

The one or more containers of the power transmission system and the decentralized data center can be modular, and can be configured to be connected to one another. This allows for the scale and functionality of the power transmission to be increased or decreased as needed. The modularity allows for scaling of the power transmission system over time. It also eliminates the need for additional major construction and/or damage to existing infrastructure.

The scalability of the system can also diminish the upfront costs of the power transmission system. There is currently a large barrier for traditional power transmission and distribution systems. Since the power transmission system described herein can be more easily scaled over time, the capital required for product purchase and installation can be spread out over the scaled time period, rather than paid up front. In some cases, the container can be designed to reduce the time of installation compared with that of traditional forms of underground cabling installation.

In some embodiments, the one or more containers and other components and accessories within the power transmission system can be prefabricated. In some cases, they can be partially or fully pre-assembled prior to arriving at the installation site, saving on assembly time and difficulty.

The customization of the containers may extend beyond aesthetics and into structural applications. The containers can be used for infrastructure applications, such as roadways, pathways, sidewalks, flooring, and/or any other form of ground-based infrastructure for outdoor or indoor purposes. The modularity of the containers enables the system to be as small as a single container or as large as is necessary for the intended application.

The one or more power sources include power harvesting devices such as solar containers, wind turbines, kinetic power harvesting devices, piezoelectric generators, triboelectric generators, or any other form of power generation, transmission, storage, or harvesting. In some cases, the power source is an electrical grid. In some cases, one or more converters may be used to step up or down the voltage at the point of the generation or elsewhere before or after it is to be transmitted. In some cases, one or more rectifiers may be used to rectify the power at the point of generation or elsewhere before or after it is to be transmitted.

In some cases, the kinetic energy harnessing devices can be implemented directly in the containers themselves. For example, power harvesting systems can harvest kinetic power exerted on system by pedestrian and/or vehicular traffic above a surface in which the containers, described herein, are embedded. By implementing the power source directly into the containers, the containers can become an integrated system for both power and data generation and transmission.

The one or more power destinations can comprise low power-consuming infrastructure such as indoor and outdoor lighting systems, street lighting systems, air conditioning (A/C) units, mobile charging stations, and/or Wi-Fi kiosks, among others. In some cases, the one or more power destinations may comprise high power-consuming infrastructure such as residential buildings, hospitals, and schools, among others. The power destination can be any destination that includes an electrical load (e.g., an electronic device, or anything that uses, consumes, or stores electricity or power).

In order to transmit power from the power source to the power destination or elsewhere, one or more wires such as transmission cables may be housed in the one or more containers. The one or more wires can connect from the power source (such as a power generating device) to the power destination (electrical load), directly or indirectly.

In some cases, the containers can be designed such that individual transmission conduits are secured to each container and disconnected from one another, thus creating a plug-and-play system with the containers. As each container is laid in the ground, the next container may conveniently plug into the one adjacent to it. In this setup, the system can be easily scaled and/or the design can change at a later point in time with no damage to the containers and their transmission cables and with little effort, so long as the plugs remain compatible.

In some embodiments, a plurality of protection systems may be included in the system to protect the system against over voltage, over current, or ground fault, among other problems. In some cases, the power transmission components can be made waterproof by housing all electrical components in a waterproof container, such as a NEMA box or similar cover.

Described herein are power and data systems for power and data generation, storage, and transmission. In some embodiments, a power and data system comprises a container as described herein. In some cases, the power and data system comprises two or more containers. In some embodiments, a power harvesting device, as described elsewhere, is integrated into at least one of the containers. Integration of the power harvesting device into the container may require changes to the container structure or design. In some cases, the change to the container structure or design is minimal.

In some embodiments, the power and data system may further comprise a power and/or data storage system. In some cases, the power and/or data storage system is integrated into at least one of the containers. The power storage system can collect and store power from the power generator. The stored power can be utilized for larger power applications that require one consistent stream of power. For example, the power storage system can be an electrochemical cell, lithium ion battery, rechargeable power storage systems, capacitors, supercapacitors or ultracapacitors, fuel cells, other cells, or any other power storage system (e.g., a system that stores potential power that can be converted to electrical power).

In some cases, the power harvesting device harvests power (e.g., generates electrical power) by harnessing kinetic energy that is applied to the power harvesting devices. The energy may be harnessed from vehicular activity. In some cases, the energy may be harnessed from pedestrian activity. In some cases, the power harnessing system may be integrated into an electrical grid or an external electrical system. The ability to install a power harnessing system any distance away from an electrical grid or an external electrical system allows for the creation of a power system with unrestricted modularity and scalability, and ease of installation and repairs. Such systems for power generation, storage, and transmission can be used to provide power in remote parts of the world without electricity.

In some embodiments, one or more micro-generators may be embedded in each container. In some cases, the micro-generator can harness power from pedestrian and vehicular traffic. The use of embedded micro-generators provides several advantages. For example, the micro-generators mitigate spatial and/or geographical constraints typically encountered with the construction of power plants. In addition, the use of micro-generators within the containers provides users with reliable, self-sustaining, on-demand electricity.

In some embodiments, the power transmission system may include an embedded power metering system that tracks power data. In some cases, the power data relates the amount of power generated by the power generating device, the amount of power available from the power source, the amount of power available for use by the power transmission system, the amount of power needed by the power destination, or a combination thereof.

In some cases, the embedded power metering system can comprise one or more direct current (DC) power meters, one or more alternate current (AC) power meters, or a combination thereof. The power meter may be purchased off-the-shelf or custom-designed, or a combination therein. The meter may collect information such as current and voltage, among others. In addition, other variables such as power and power can be derived from the power meter.

In some cases, a smart power meter can be used. A smart power meter may provide several advantages over a regular meter. A regular meter connects to a server to transfer data collected by the meter to the server. A smart power meter, however, may contain internal storage to store the data collected. In the event that the server is down, data can be temporarily stored for weeks or more, as needed. A smart power meter may be able to connect to the Internet directly so that it can directly upload or publish data to a cloud system or otherwise communicate directly. The smart power meter may comprise a network adapter, for example, to communicate with a network (e.g., the Internet).

The power meter may be customized so that it can be integrated directly into the server. One benefit to this integration is that the system takes up less physical space. Another benefit is that once integrated into the server, the server is able to control the power meter, thus creating a smart meter. The server may be programmed to collect certain information on its own according to set protocols.

Once the data is collected from the meter, it can be stored on site, sent to the cloud via a server for storage, or a combination of the two. The data may later be analyzed, evaluated, and used for other applications. The data can help to understand the power production and/or usage of the system. The operators of the system can identify how much power the system itself used and how much power the loads used. For example, from this data, the consumers can be billed according to their load usage.

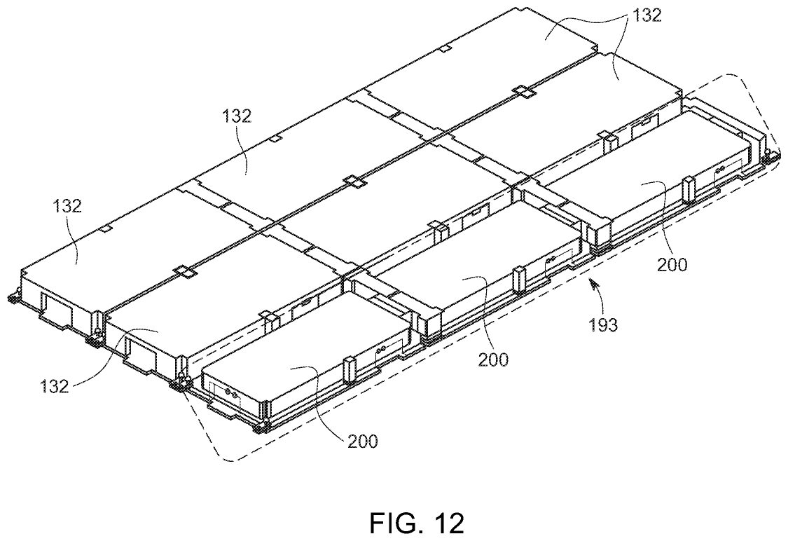

FIG. 12 is a structural arrangement of container systems 132 and container subsystems 200. As shown, in FIG. 12, a plurality of container systems 132 can be oriented in a parallel configuration. Further, oriented along the edge are a plurality of container subsystems 200. The communication between the container subsystem 200 and container system 132 can provide additional functions. For example, the container sub system 200 can enable storage, protection, monitoring, and communication for third-party devices. The third party devices can be companies that use the container subsystem to acquire their own data. In addition to data acquisition, certain companies that provide internet of things (capabilities) can utilize a container subsystem with a localized source of continuous, reliable, and modular power. The power supply and data acquisition components from the sensor network would be available and secured through the protective casing of the container subsystem 200.

In a further aspect, the orientation and variability in structural coupling of the container system 132 and container subsystem 200 can impact variable-resolution edge colocation. For example, a high resolution for the colocation space in the container subsystem can aid in achieving low latency communication. Further, increasing the number of container subsystems 200 can result in increasing the colocation space resolution. The colocation space resolution is the geospatial resolution of the signal provided by the power/data distribution devices in the container subsystem. In addition, the resolution of colocation space affects the total power required for the container installation but does not affect power transmission for individual colocation spaces. Data transmission is impacted by increasing colocation resolution as the bandwidth for the colocation space remains constant, thereby reducing the available individual bandwidths for data distribution.

The structure of the container systems and subsystems allow rental customers to customize the scale of their system. The edge system 193 can be easily expanded over time as needs grow. This scalability means it is not necessary to know the client's future needs at the time of installation. The arrangement of container systems 132 and subsystems 200 can be as small or as large as is needed and can be scaled slowly or rapidly over time. Similarly descaling of the system can be supported without comprising the required power and data needs for the overall configuration. In further aspects, the physical arrangement of the container system 132 and container subsystem 200 can be configured as a 2-lane arrangement, 3-lane arrangement, or other embodiments with angled (e.g., 90 degree) turns.

In some cases, data relating to system's power and data usage can be used to generate predictions as to what loads will need power and data and of what amounts in the future, and where along a deployed system. The system may be able to integrate protocols to prepare for such predictions by ensuring enough power and data are available for the associated loads and/or at certain times of the day.

In some embodiments, the power transmission system may include a monitoring system. In some cases, the monitoring system tracks one or more performance metrics of one or more transmission lines embedded underground. By monitoring one or more performance metrics, any breakage or fault of transmission lines may be quickly and easily detected, and may be repaired faster when compared to a similar situation without the above monitoring system.

While certain embodiments of the disclosure have been described in connection with what is presently considered to be the most practical and various embodiments, it is to be understood that the disclosure is not to be limited to the disclosed embodiments, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain embodiments of the disclosure, including the best modes, and also to enable any person skilled in the art to practice certain embodiments of the disclosure, including making and using any devices or systems and performing any incorporated methods. The patentable scope of certain embodiments of the disclosure is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A plurality of modular containers comprising:
a first container comprising:
a first top surface, a first bottom surface and at least one first side surface oriented between the first top and the first bottom surface,
a first internal cavity;
a container system in the first internal cavity comprising
a power distribution system and
a data distribution system;
a second container comprising:
a second top surface, a second bottom surface and at least one second side surface oriented between the second top and the second bottom surface,
a second internal cavity; and
a container subsystem in the second internal cavity
wherein the container system is in communication with the container subsystem.

2. The plurality of modular containers of claim 1, wherein the first container and the second container further comprise first container ports and second container ports, respectively.

3. The plurality of modular containers of claim 2, wherein the container subsystem further comprises a container subsystem entrance ports or a container subsystem exit ports.

4. The plurality of modular containers of claim 3, wherein the container subsystem entrance port or container subsystem exit port is aligned with the first container ports or the second container ports.

5. The plurality of modular containers of claim 1, wherein the power distribution system adjusts a power supplied to the container subsystem.

6. The plurality of modular containers of claim 1, wherein the container system provides container system data to the container subsystem.

7. The plurality of modular containers of claim 6, wherein the container subsystem is configured to communicate on a network externally from the container system data provided by the container system.

8. The plurality of modular containers of claim 1, wherein the container system is in a container system enclosure that is configured to withstand environmental conditions.

9. The plurality of modular containers of claim 1, wherein the container system further comprises container system monitoring sensor configured to monitor container system data.

10. The plurality of modular containers of claim 9, wherein the container system monitoring sensor is configured to monitor container subsystem data.

11. The plurality of modular containers of claim 1, further comprising a conduit transmitting through the first container at least one of: electricity, light, solid, liquid, or gas.

12. The plurality of modular containers of claim 1, further comprising at least one external sensor monitoring factors external to the first or second containers.

13. The plurality of modular containers of claim 1, wherein the first container further comprises at least one internal sensor configured to monitor internal factors of the first container.

14. A plurality of modular containers comprising:
a first container comprising:
a first top surface, a first bottom surface and at least one first side surface oriented between the first top and the first bottom surface,
a first internal cavity;
a container system in the first internal cavity transmitting container system data;
a second container comprising:
a second top surface, a second bottom surface and at least one second side surface oriented between the second top and the second bottom surface,
a second internal cavity; and
a container subsystem in the second internal cavity
wherein the container system is in communication with the container subsystem.

15. The plurality of modular containers of claim 14, further comprising a power distribution system that adjusts a power supplied to the container subsystem.

16. The plurality of modular containers of claim 14, wherein the container system communicates the container system data to the container subsystem.

17. The plurality of modular containers of claim 14, wherein the container subsystem is configured to communicate on a network externally from the container system.

18. The plurality of modular containers of claim 16, wherein the container system stores, monitors the container system data.

19. A modular container comprising:
a first top surface, a first bottom surface, and at least one first side surface oriented between the first top and the first bottom surface,
a first internal cavity;
a conduit transmitting through the modular container at least one of: electricity, light, solid, liquid, or gas;
a container subsystem in the first internal cavity,
wherein the container subsystem stores, monitors, and communicates the modular container data.

20. The modular container of claim 19 further comprising a container system in the first internal cavity comprising a power distribution system and a data distribution system.
